(19) United States
(12) Patent Application Publication
(10) Pub. No.: US 2015/0184287 A1
(43) Pub. Date: Jul. 2, 2015

(54) Systems and Methods for Parallel Combinatorial Vapor Deposition Processing

(71) Applicant: Intermolecular, Inc., San Jose, CA (US)

(72) Inventors: James Tsung, Milpitas, CA (US); Tony P. Chiang, Campbell, CA (US); Chien-Lan Hsueh, Campbell, CA (US)

(73) Assignee: Intermolecular, Inc., San Jose, CA (US)

(21) Appl. No.: 14/140,874

(22) Filed: Dec. 26, 2013

(51) Int. Cl. C23C 16/44; C23C 16/455; C23C 16/04

(52) U.S. Cl. CPC C23C 16/44; C23C 16/04; C23C 16/45561

(57) ABSTRACT

Embodiments described herein provide systems and methods for performing vapor deposition processes on substrates. A housing defining a processing chamber is provided. A substrate support is positioned within the processing chamber and configured to support a substrate. A fluid supply system including a plurality precursor sources is included. A fluid conduit assembly is coupled to the fluid supply system and configurable to selectively expose a first site-isolated region defined on the substrate to the respective precursors of a first and a second of the plurality of precursor sources and selectively expose a second site-isolated region defined on the substrate to the respective precursors of a third and a fourth of the plurality of precursor sources.

### TECHNICAL FIELD

The present invention relates to vapor deposition processing. More particularly, this invention relates to systems and methods for combinatorial vapor deposition processing.

### BACKGROUND OF THE INVENTION

Combinatorial processing enables rapid evaluation of, for example, semiconductor and solar processing operations. The systems supporting the combinatorial processing are flexible to accommodate the demands for running the different processes either in parallel, serial or some combination of the two.

Some exemplary processing operations include operations for adding (depositions) and removing layers (etch), defining features, preparing layers (e.g., cleans), conversion of layers or surfaces, doping, etc. Similar processing techniques apply to the manufacture of integrated circuit (IC) semiconductor devices, flat panel displays, optoelectronics devices, data storage devices, magneto electronic devices, magneto optic devices, packaged devices, and the like. As manufacturing processes continue to increase in complexity, improvements, whether in materials, unit processes, or process sequences, are continually being sought for the multi-step processing sequence.

However, semiconductor, thin-film-coating, and solar companies conduct research and development (R&D) on full wafer and (glass) substrate processing through the use of split lots, as the conventional deposition systems are designed to support this processing scheme. This approach has resulted in ever escalating R&D costs and the inability to conduct extensive experimentation in a timely and cost effective manner. Combinatorial processing as applied to semiconductor, solar, or energy-efficiency manufacturing operations enables multiple experiments to be performed at one time in a high throughput manner. Equipment for performing the combinatorial processing and characterization must support the efficiency offered through the combinatorial processing operations. The debottlenecking of the R&D efforts involves the above fast processing platforms in combination with throughput-matched characterization and fast automated data capture and analysis, in addition to accelerated lifetime testing and product simulations to allow a fast guidance for subsequent design of experiments to unravel the correlations between materials, processing, equipment, and product performance and durability.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration that includes site isolated processing and/or conventional processing according to some embodiments.

FIG. 3 is a simplified schematic diagram illustrating an integrated high productivity combinatorial (HPC) system according to some embodiments.

FIG. 4 is a cross-sectional schematic view of a vapor deposition processing system according to some embodiments.

FIG. 5 is an isometric view of a showerhead within the vapor deposition processing system of FIG. 4 according to some embodiments.

FIG. 6 is a plan view of the showerhead of FIG. 5.

FIG. 7 is simplified schematic view of a section of the vapor deposition processing system of FIG. 4 according to some embodiments.

FIG. 8 is simplified schematic view of multiple sections of the vapor deposition processing system of FIG. 4 according to some embodiments.

FIG. 9 is an isometric view of a fluid conduit assembly according to some embodiments.

FIG. 10 is an isometric view of a fluid conduit assembly according to some embodiments.

FIG. 11 is a flow chart illustrating a method for performing a vapor deposition process on a substrate according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide combinatorial vapor deposition systems (or tools) and methods, such as those for performing atomic layer deposition (ALD) and chemical vapor deposition (CVD), that allow each site-isolated region on a substrate to be exposed to multiple precursors, and in some embodiments, multiple reactants as well.

As such, the embodiments described herein provide, for example, combinatorial ALD and CVD processing tools with an increased range of combinatorial processing as multiple, completely different/unique sets of precursors and/or reactants may be used on each of the site-isolated regions.

As such, in accordance with some embodiments, combinatorial processing may be used to produce and evaluate different materials, substrates, chemicals, processes, coating stacks, and techniques related to various materials, barrier layers, nucleation layers, and adhesion layers, as well as build structures or determine how materials coat, fill or interact with existing structures in order to vary materials, unit processes and/or process sequences across multiple site-isolated regions on the substrate(s). These variations may relate to specifications such as temperatures, exposure times, layer thicknesses, chemical compositions of majority and minority elements of layers, gas compositions, chemical compositions of wet and dry surface chemistries, power and pressure of sputter deposition conditions, humidity, etc. of the formulations and/or the substrates at various stages of the screening processes described herein. However, it should be noted that in some embodiments, the chemical composition remains the same, while other parameters are varied, and in other embodiments, the chemical composition is varied.

The manufacture of various devices, such as semiconductor devices, photovoltaic devices, electrochromic devices, etc., entails the integration and sequencing of many unit processing steps. For example, device manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power consumption, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration,” on a single monolithic substrate (e.g., an integrated or short-looped wafer) without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574, filed on Feb. 10, 2006, U.S. Pat. No. 7,824,935, filed on Jul. 2, 2008, U.S. Pat. No. 7,871,928, filed on May 4, 2009, U.S. Pat. No. 7,902,063, filed on Feb. 10, 2006, and U.S. Pat. No. 7,947,531, filed on Aug. 28, 2009, which are all herein incorporated by reference. Systems and methods for HPC processing are further described in U.S. patent application Ser. No. 11/352,077, filed on Feb. 10, 2006, claiming priority from Oct. 15, 2005, U.S. patent application Ser. No. 11/419,174, filed on May 18, 2006, claiming priority from Oct. 15, 2005, U.S. patent application Ser. No. 11/674,132, filed on Feb. 12, 2007, claiming priority from Oct. 15, 2005, and U.S. patent application Ser. No. 11/674,137, filed on Feb. 12, 2007, claiming priority from Oct. 15, 2005, which are all herein incorporated by reference.

HPC processing techniques have been successfully adapted to wet chemical processing such as etching and cleaning. HPC processing techniques have also been successfully adapted to deposition processes such as, atomic layer deposition (ALD), chemical vapor deposition (CVD), and physical vapor deposition (PVD).

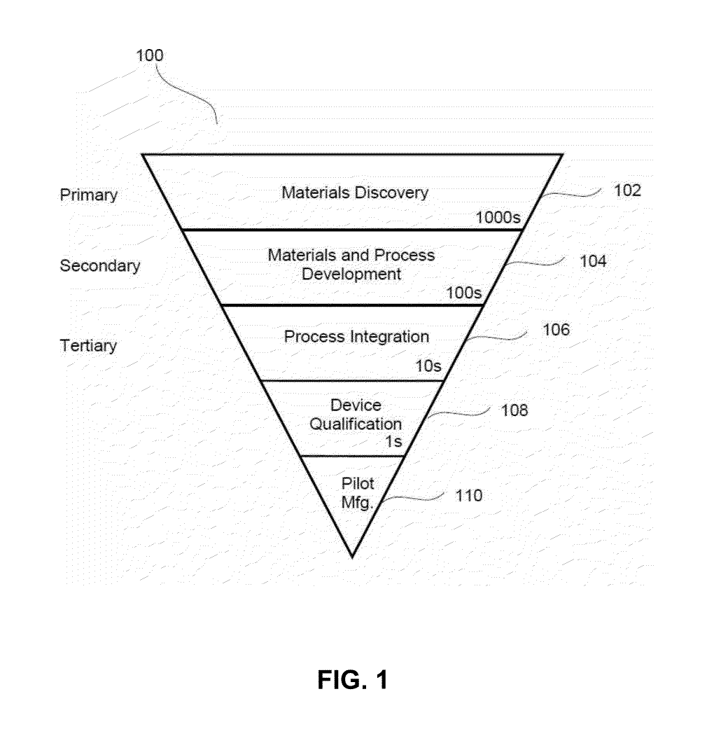

FIG. 1 illustrates a schematic diagram 100 for implementing combinatorial processing and evaluation using primary, secondary, and tertiary screening. The schematic diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

Although not shown, an initial stage may be implemented which includes a fast screening/search of structure-material property relationships, known process-material relationships, known stack-product (device) relationships, etc. within any available literature prior to starting any experimentation that results in materials discovery. After this initial stage, for example, thousands of materials are evaluated during a materials discovery stage, 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as ellipsometers, XRF, stylus profilers, hall measurements, optical transmission, reflection, and absorption testers, electronic testers and imaging tools (i.e., microscopes).

The materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106, where tens of materials and/or processes and combinations are evaluated. The tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing 110.

The schematic diagram 100 is an example of various techniques that may be used to evaluate and select materials and processes for the development of new materials and processes.

The descriptions of primary, secondary, etc. screening and the various stages 102-110 are arbitrary and the stages may overlap, occur out of sequence, be described and be performed in many other ways.

This application benefits from High Productivity Combinatorial (HPC) techniques described in U.S. patent application Ser. No. 11/674,137, filed on Feb. 12, 2007, which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of, for example, device manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate(s) that are equivalent to the structures formed during actual production of the device. For example, such structures may include, but would not be limited to, contact layers, buffer layers, absorber layers, or any other series of layers or unit processes that create an intermediate structure found on devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate(s) during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate, or substrates, that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate(s) can be defined as needed, but are preferably systematized for ease of tooling and design of experimentation. In addition, the number, variants and location of structures within each region are designed to enable valid statistical analysis of the test results within each region and across regions to be performed.

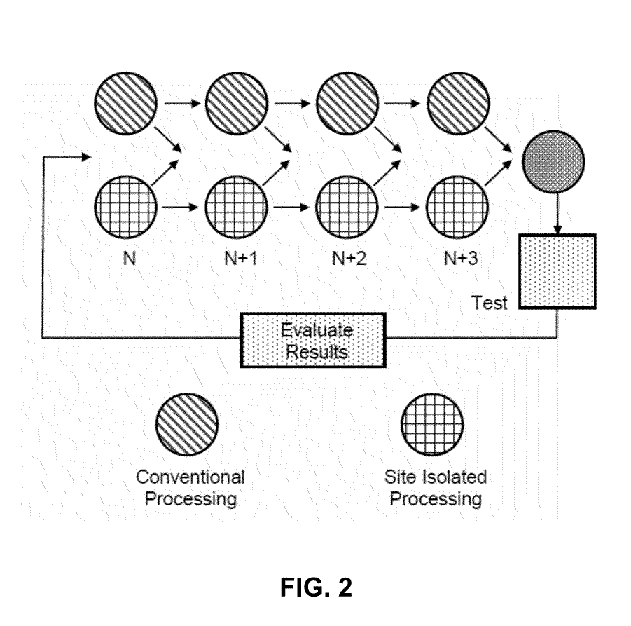

FIG. 2 is a simplified schematic diagram illustrating a general methodology for combinatorial process sequence integration that includes site isolated processing and/or conventional processing in accordance with some embodiments. In some embodiments, the substrate(s) is initially processed using conventional process N. In some embodiments, the substrate is then processed using site isolated process N+1. During site isolated processing, an HPC module may be used, such as the HPC module described in U.S. patent application Ser. No. 11/352,077, filed on Feb. 10, 2006. The substrate(s) can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations, the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate, or from substrate to substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in device manufacturing may be varied.

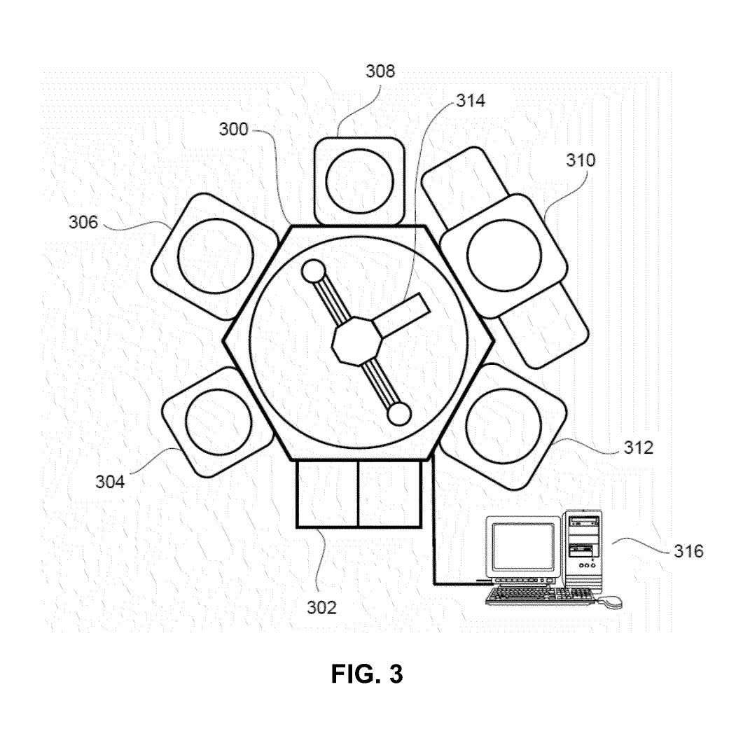

FIG. 3 is a simplified schematic diagram illustrating an integrated high productivity combinatorial (HPC) system according to some embodiments. HPC system includes a frame 300 supporting a plurality of processing modules. It should be appreciated that frame 300 may be a unitary frame in accordance with some embodiments. In some embodiments, the environment within frame 300 is a controlled atmosphere (or environment). As used herein, the phrase “controlled atmosphere” and “controlled environment” will be understood to be equivalent and will be understood to include one of a vacuum, or an inert gas. Examples of inert gases include helium, neon, argon, krypton, xenon, and nitrogen, as well as combinations thereof.

Still referring to FIG. 3, load lock/factory interface 302 provides access into the plurality of modules of the HPC system. Robot 314 provides for the movement of substrates (and masks) between the modules and for the movement into and out of the load lock 302. Modules (or processing tools) 304-312 may be any set of modules and preferably include one or more combinatorial modules. For example, module 304 may be a deposition (e.g., atomic layer deposition (ALD), chemical vapor deposition (CVD) physical vapor deposition (PVD) etc.) module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, e.g., computing device 316, may control the processes of the HPC system, including the power supplies and synchronization of the duty cycles described in more detail below. Further details of one possible HPC system are described in U.S. application Ser. No. 11/672,478 filed Feb. 7, 2007, now U.S. Pat. No. 7,867,904 and claiming priority to U.S. Provisional Application No. 60/832,248 filed on Jul. 19, 2006, and U.S. application Ser. No. 11/672,473, filed Feb. 7, 2007, and claiming priority to U.S. Provisional Application No. 60/832,248 filed on Jul. 19, 2006, which are all herein incorporated by reference. With HPC system, a plurality of methods may be employed to deposit material upon a substrate employing combinatorial processes.

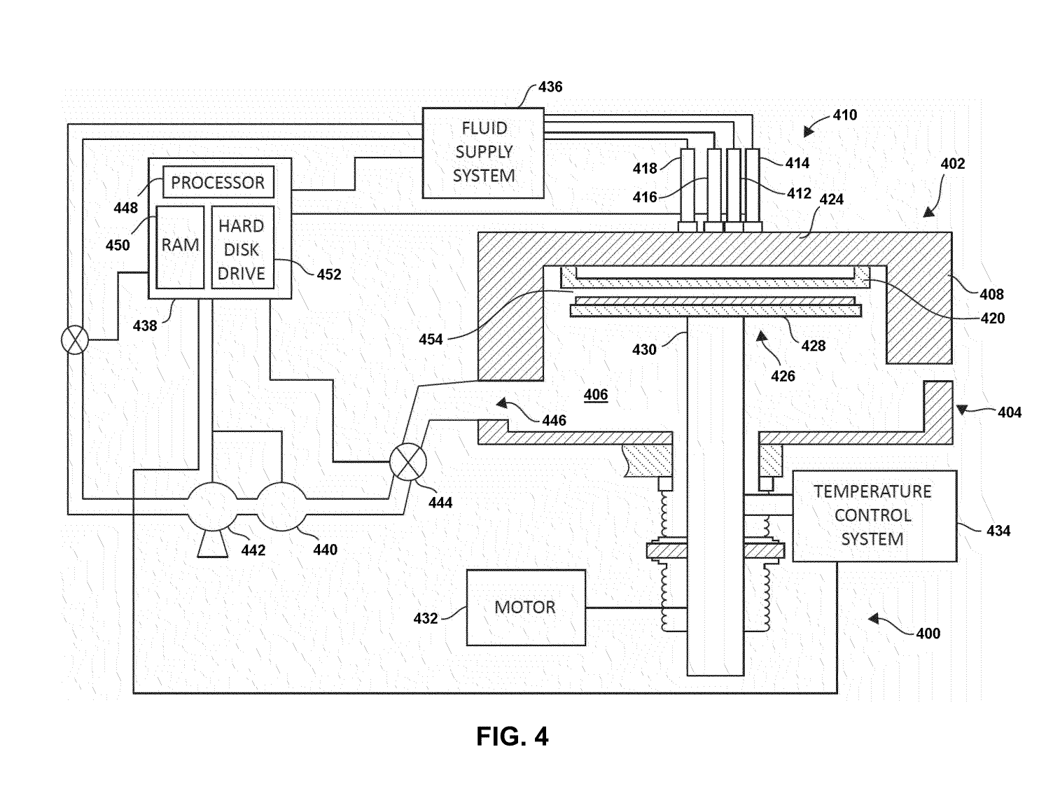

FIG. 4 illustrates an ALD (or CVD) processing module (or system or tool) 400 according to some embodiments. The processing module 400 may be one of the processing modules 304-312 in the system shown in FIG. 3.

The module 400 includes an enclosure assembly 402 formed from a process-compatible material, such as aluminum or anodized aluminum. The enclosure assembly 402 includes a housing 404, which defines a processing chamber 406, and a vacuum lid assembly 408 covering an opening to the processing chamber 406 at an upper end thereof. Although only shown in cross-section, it should be understood that the processing chamber 406 is enclosed on all sides by the housing 404 and/or the vacuum lid assembly 408.

A fluid conduit assembly 410 is mounted to the vacuum lid assembly 408 and includes a plurality of fluid conduit branches (or injection ports) 412, 414, 416, and 418 and a showerhead 420 to deliver processing fluids (e.g., precursors, reactants, and carrier fluids) into the processing chamber 406. The showerhead 420 may be moveably coupled to an upper portion of the vacuum lid assembly 408 (i.e., a backing plate 424). The showerhead 420 may be formed from any known material suitable for the application, including stainless steel, aluminum, anodized aluminum, nickel, ceramics and the like. In some embodiments, the showerhead 420 may be considered a component separate from the fluid conduit assembly.

Referring again to FIG. 4, the module 400 also includes a heater/lift assembly 426 disposed within processing chamber 406. The heater/lift assembly 426 includes a support pedestal (or substrate support) 428 connected to an upper portion of a support shaft 430. The support pedestal 428 is positioned between shaft 430 and the backing plate 424 and may be formed from any process-compatible material, including aluminum nitride and aluminum oxide. The support pedestal 428 is configured to hold or support a substrate and may be a vacuum chuck, as is commonly understood, or utilize other conventional techniques, such as an electrostatic chuck (ESC) or physical clamping mechanisms, to prevent the substrate from moving on the support pedestal 428. The support shaft 430 is moveably coupled to the housing 404 so as to vary the distance between support pedestal 428 and the backing plate 424. That is, the support shaft 430 may be vertically moved to vary the distance between the support pedestal 428 and the backing plate 424. In the depicted embodiment, a lower portion of the support shaft 430 is coupled to a motor 432 which is configured to perform this movement. Although not shown, a sensor may provide information concerning the position of the support pedestal 428 within processing chamber 406.

The support pedestal 428 may be used to heat the substrate through the use of heating elements (not shown) such as resistive heating elements embedded in the pedestal assembly. In the embodiment shown in FIG. 4, a temperature control system 434 is provided to control the heating elements, as well as maintain the chamber housing 404, vacuum lid assembly 408, and showerhead 420 within desired temperature ranges in a conventional manner.

Still referring to FIG. 4, the module 400 also includes a fluid supply system 436 and a controller (or system control system) 438. The fluid supply system 436 is in fluid communication with the fluid conduit branches 412, 414, 416, and 418 through a sequence of fluid conduits (or fluid lines).

The fluid supply system 436 (and/or the controller 438) controls the flow of processing fluids to, from, and within the processing chamber 406 with a pressure control system that includes, in the embodiment shown, a turbo pump 440 and a roughing pump 442. The turbo pump 440 and the roughing pump 442 are in fluid communication with processing chamber 406 via a butterfly valve 444 and a pump channel 446. Although not shown, the fluid supply system 436 may include a plurality of processing fluid supplies (or sources) which include various processing fluids, such as reagents (e.g., precursors (or sources) and/or reactants (or oxidants)) for performing ALD (or CVD) processing, as is commonly understood. In some embodiments, the fluid supply system 436 (and/or the module 400 as a whole) also includes one or more vacuum lines (e.g., coupled to a “house vacuum” as is commonly understood). Further, the fluid supply system 436 (and/or the fluid conduit assembly 410) may includes various components for controlling the flow of processing fluids, such as valves, mass flow controllers (MFCs), etc.

The controller 438 includes a processor 448 and memory, such as random access memory (RAM) 450 and a hard disk drive 452. The controller 438 is in operable communication with the various other components of the processing module 400, including the turbo pump 440, the temperature control system 434, the fluid supply system 436, and the motor 432 and controls the operation of the entire processing module to perform the methods and processes described herein.

During operation, the module 400 establishes conditions in a processing region 454 between an upper surface of the substrate and the showerhead 420, such as injecting precursors (or reagents), as well as purge gases, to form the desired material on the surface of the substrate. In particular, in some embodiments, the fluid supply system 436 provides various processing fluids (e.g., precursors, reactants, etc.) to the showerhead 420, from which the fluids flow onto the substrate to, for example, form a layer of material on the substrate (e.g., via ALD).

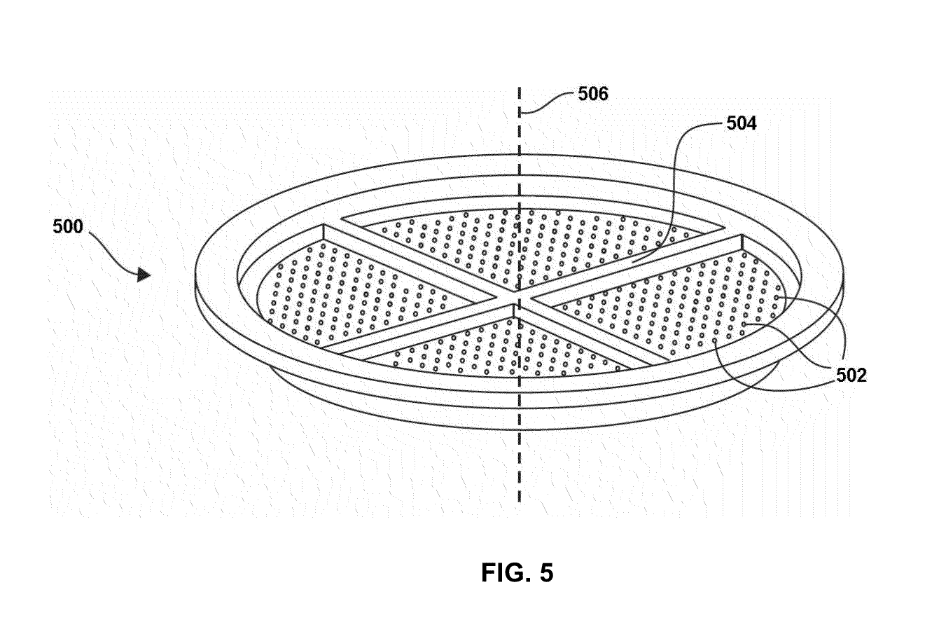

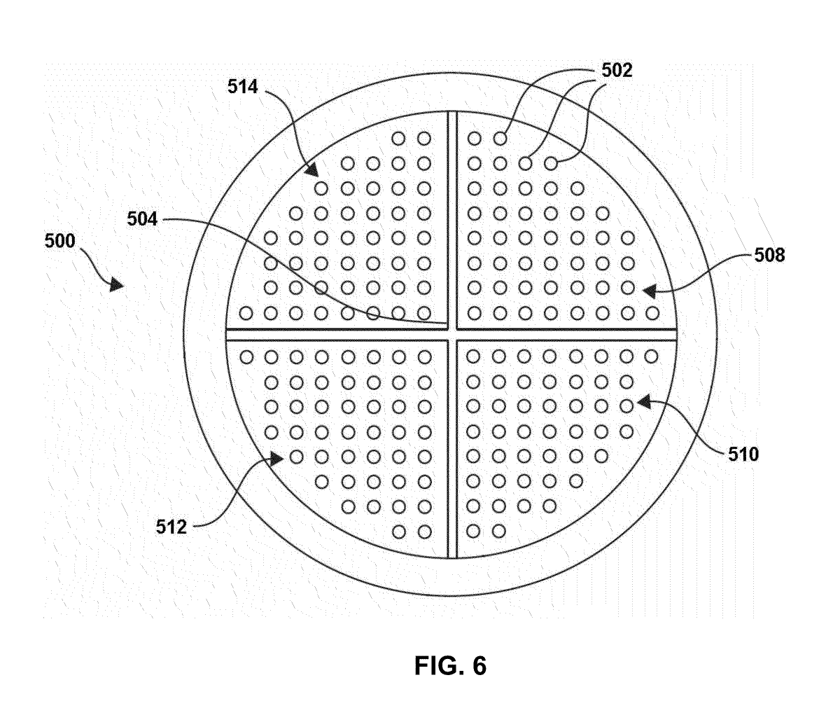

FIGS. 5 and 6 illustrate a showerhead 500 (e.g., showerhead 420 in FIG. 4) according to some embodiments. In some embodiments, the showerhead 500 is substantially circular and has a diameter of, for example, between about 200 millimeters (mm) and about 500 mm. The showerhead 500 includes a plurality of injection ports (or openings) 502 extending therethrough and a fluid separation mechanism 504 that, in the depicted embodiments, extends upwards from a central portion of a main body of the showerhead 500. Although not shown in detail, each of the injection ports 502 may have a diameter that varies as it extend through the showerhead 500, with a larger diameter near the upper surface of the showerhead 500 (i.e., near the fluid separation mechanism 504). The showerhead 500 may be made of from any known material suitable for the application, including stainless steel, aluminum, anodized aluminum, nickel, ceramics and the like.

In the depicted embodiment, the fluid separation mechanism 504 includes several substantially linear portions of material that meet at a central axis 506 of the showerhead 500 and divide the showerhead 500 (and/or the injection ports 502) into four regions (or portions) or quadrants 508, 510, 512, and 514 (FIG. 6), each of which may be aligned with a respective one of the fluid conduit branches 412, 414, 416, and 418 (FIG. 4). The distance that fluid separation mechanism 504 extends from the main body of the showerhead 500 is dependent upon the specific design parameters and may vary in different embodiments. However, in at least some embodiments, the fluid separation mechanism 504 provides sufficient separation to minimize, if not prevent, fluids from diffusing between the different portion 508-514 of the showerhead 500.

It should be understood that each of the portions 508-514 of the showerhead 500 may correspond to a site-isolated region defined on the substrate being processed. That is, processing fluids delivered to each of the portions 508-514 may flow through the respective injection ports 502 (i.e., the injection ports 502 within that portion) to process a region on the substrate (e.g., having about the same size and shape as the respective portion of the showerhead 500) in a site-isolated manner. As such, the portions 508-514 of the showerhead 500 shown in FIG. 5 may also be considered to represent the site-isolated regions on the substrate. Thus, the showerhead 500 (and/or the module 400 as a whole) is capable of processing different regions on the substrate in a site-isolated (and perhaps combinatorial) manner.

In some embodiments, the fluid separation mechanism 504 may include (or be made of) a series of channels extending across the main body of the showerhead 500, or additional injection ports 502, through which a processing fluid (e.g., an inert gas, such as argon) may be flown to “block” the other processing fluids from flowing between the quadrants 508-514. It should be understood that in some embodiments the fluid separation mechanism 504 divides the showerhead 500 into a different number (and size/shape) of portions (e.g., two, three, or more than four portions), thereby also defining a different number (and/or size/shape) of site-isolated regions on the substrate.

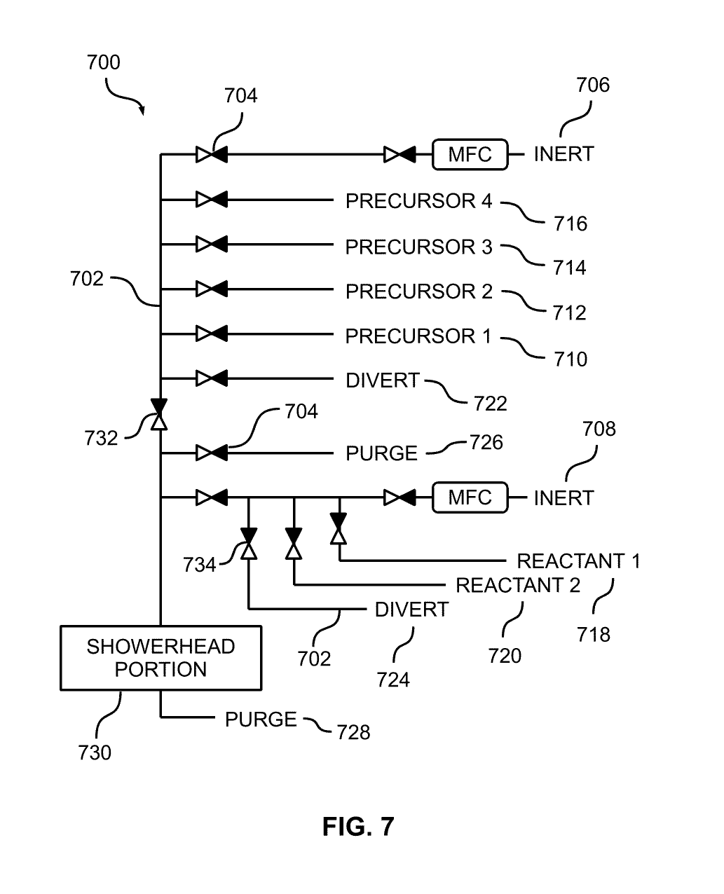

FIG. 7 is a simplified schematic illustration of a section (or portion) 700 of, for example, the module 400 (FIG. 4). As is described in greater detail below, the section 700 may correspond to (and/or include) portions of the fluid supply system 436, the fluid conduit assembly 410, such as one of the fluid conduit branches 412-418 (FIG. 4), and/or the showerhead 500 (FIG. 5).

The section 700 includes an array of fluid conduits (or passageways) 702 and valves 704 which interconnect (or place in fluid communication) the various other components in FIG. 7 in the manner shown. In some embodiments, the fluid conduits 702 and the valves 704 interconnect (and/or the section 700 further includes) first and second inert (or carrier) gas sources 706 and 708 (including MFCs), precursor sources 710, 712, 714, and 716 (i.e., first, second, third, and fourth precursor sources), reactant sources 718 and 720 (i.e., first and second reactant sources), divert (or “dump”) lines 722 and 724, purge lines 726 and 728, and a showerhead portion 730. The precursor sources 710-716, the reactant sources 718 and 720, and the inert gas sources 706 and 708 may refer to various sources (or supplies) of appropriate processing fluids within the fluid supply system 436 (FIG. 4). Purge line 726 may be in fluid communication with an inert gas source (e.g., argon), similar to the inert gas sources 706 and 708. The divert lines 722 and 724 and purge line 728 may be in fluid communication with vacuum lines.

The showerhead portion 730 may refer to one of the portions (e.g., quadrants) 508-514 of the showerhead 500 shown in FIGS. 5 and 6. It should also be understood that the section 700, and all of the components shown in FIG. 7, may be replicated for each of the portions 508-514 of the showerhead 500 (regardless of the number of portions into which the showerhead is divided). That is, the module 400 (FIG. 4) may include a section (e.g., section 700) for each of the portions 508-514 of the showerhead 500. Thus, the section(s) 700 may include a dedicated set of the components shown in FIG. 7 for each of the portions 508-514 of the showerhead 500 (and thus a set for each of the site-isolated regions on the substrate to be processed).

As such, still referring to FIG. 7, the fluid conduits 702 and the valves 704 are configurable to selectively place the showerhead portion 730 in fluid communication with the various fluid sources (e.g., the precursor sources 710-716 and the reactant sources 718 and 720) and vacuum lines (e.g., the divert lines 722 and 724) shown in FIG. 7. Of particular interest is that the showerhead portion 730 may be selectively placed in fluid communication with (and/or exposed to) more than one (e.g., four for each showerhead portion) precursor sources and more than one (e.g., two for each showerhead portion) reactant sources.

Thus, each showerhead portion 730 (and thus the corresponding site-isolated region on the substrate) may be exposed to multiple combinations of precursors and reactants (e.g., via the respective section 700). For example, the showerhead portion 730 may first be exposed to precursor source (or precursor) 710, and then be exposed to reactant source (or reactant) 718, to perform a first process (e.g., a first ALD cycle) on the respective site-isolated region on the substrate. As will be appreciated by one skilled in the art, the gas from the first inert gas source 706 may be used as a carrier gas to deliver the precursors to the showerhead portion 730, while the gas from the second inert gas source 708 may be used as a carrier gas to deliver the reactants to the showerhead portion 730.

The showerhead portion 730 may then be exposed to precursor 712, followed by reactant 720, to perform a second process (e.g., a second ALD cycle) on the respective site-isolated region on the substrate. The showerhead portion 730 may be purged (e.g., between the first and second processes) by flowing an inert gas (e.g., argon) from purge line 726 through the showerhead portion 730, where it (along with any possible contaminants) is disposed of through purge line 728.

It should also be noted that the fluid conduits 702 (and/or the valves 704) allow the various precursors and reactants to be diverted away from the showerhead portion 730 before reaching the showerhead portion 730. For example, precursors may be flowed from their respective sources and “dumped” through divert line 722 (which is coupled between precursor sources 710-716 and the showerhead portion 730) when valve 732 is close. Likewise, reactants may be flowed from their respective sources and dumped though divert line 724 (which is coupled between reactant sources 718 and 720 and the showerhead portion 730) when valve 734 is closed. Additionally, the fluids conduits 702/valves 704 are configurable flow fluids from more than one fluid source (e.g., a precursor and a reactant) to the showerhead portion 730 simultaneously if so desired.

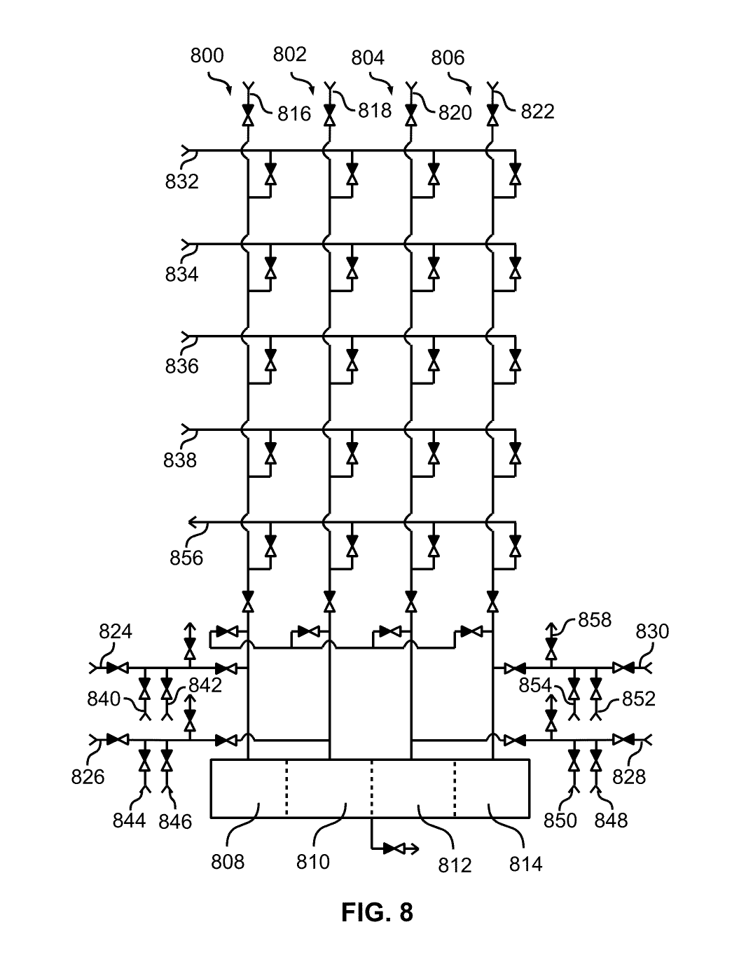

FIG. 8 is a schematic illustration of multiple (e.g., four) sections 800, 802, and 804, and 806 of, for example, the module 400 (FIG. 4). As is evident from comparing FIGS. 7 and 8, each of the sections 800-806 are similar to the section 700 shown in FIG. 7. That is, each section 800-806 includes an array of fluid conduits and valves configurable to place multiple precursor sources and multiple reactant source in fluid communication with a respective one of the portions 808, 810, 812, and 814 of a showerhead (e.g., showerhead 500 in FIGS. 5 and 6). In particular, inlets (or inlet ports) 816, 818, 820, and 822, each being associated with one of the sections 800-806, may be in fluid communication with inert (or carrier) gas sources, which may be used to carry precursors. Inlets 824, 826, 828, and 830, each being associated with one of the section 800-806, may also be in fluid communication with inert gas sources and may be used to carry reactants.

In the depicted embodiment, precursor sources are shared by sections 800-806. In particular, inlets 832, 834, 836, and 838 may be in fluid communication with respective precursor sources, and each may be accessed by all sections 800-806 using the various valves in the system. However, even in such an embodiment, each of the sections 800-806 (and the corresponding portion of the showerhead) may utilize (or be exposed to) multiple (e.g., four) precursor sources.

Inlets 840 and 842 (associated with section 800), inlets 844 and 846 (associated with section 802), inlets 848 and 850 (associated with section 804), and inlets 852 and 854 (associated with section 806) may each be in fluid communication with a respective reactant source such that each of the sections 800-806 (and the corresponding portion of the showerhead) may utilize (or be exposed to) multiple (e.g., two) reactant sources. However, although not specifically shown, in some embodiments, inlets 840, 844, 848, and 852 are in fluid communication with a first reactant source, while inlets 842, 846, 850, and 854 are in fluid communication with a second reactant source (i.e., the system as a whole may only utilize two reactants, but each of the sections 800-806 may utilize each of the two reactants). Various outlets (or outlet ports), such as outlets 856 and 858, are also provided to facilitate, for example, the divert (or dump) and purge functions described above with respect to FIG. 7.

In a manner similar to that described with respect to FIG. 7, each of the sections 800-806 may be configurable to expose the respective one of the showerhead portions 808-814 to multiple combinations or precursors and/or reactants. For example, showerhead portion 808 may first be exposed to first precursor source via inlet 832, and then be exposed to a first reactant via inlet 840, to perform a first process (e.g., a first ALD cycle) on the respective site-isolated region on the substrate. Showerhead portion 808 may then be exposed to a second precursor through inlet 834, followed by a second reactant, to perform a second process (e.g., a second ALD cycle) on the respective site-isolated region on the substrate. Showerhead portion 810 may be exposed in a similar manner using, for example, different processing conditions (e.g., a different combination of precursors and/or reactants), which may be performed at the same time as the exposing of showerhead portion 808 to the respective combination of precursors and/or reactants.

As such, the systems described herein allow for site-isolated regions on the substrate to be processed in a combinatorial manner with an increased range of processing condition variations. In particular, the systems described herein allow for combinatorial vapor deposition processing in which each site-isolated region may be processed with multiple, completely different/unique sets of precursors and/or reactants.

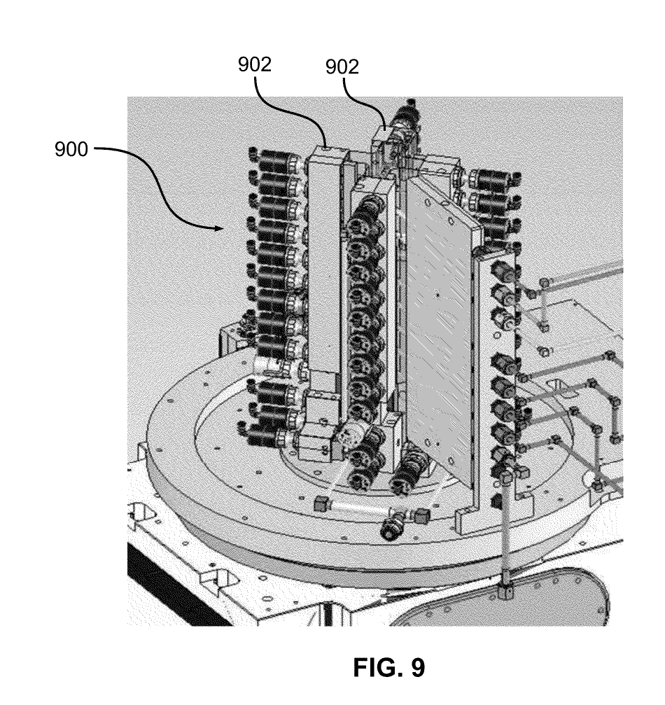

FIG. 9 illustrates a fluid conduit assembly 900 (or at least a portion thereof) according to some embodiments. Of particular interest in FIG. 9 is that the fluid conduit assembly 900 includes multiple (e.g., four) fluid conduit blocks 902. In some embodiments, each of the fluid conduits blocks 902 is associated with one of the sections (e.g., sections 800-806) of the module 400. More particularly, in some embodiments, each of the fluid conduit blocks 902 is used to form at least some of the fluid conduits within the respective section of the module (e.g., more than one fluid conduit may be formed by a passageway within each fluid conduit block 902). The fluid conduit block 902 may be made of single, integral pieces of material (e.g., steel or aluminum).

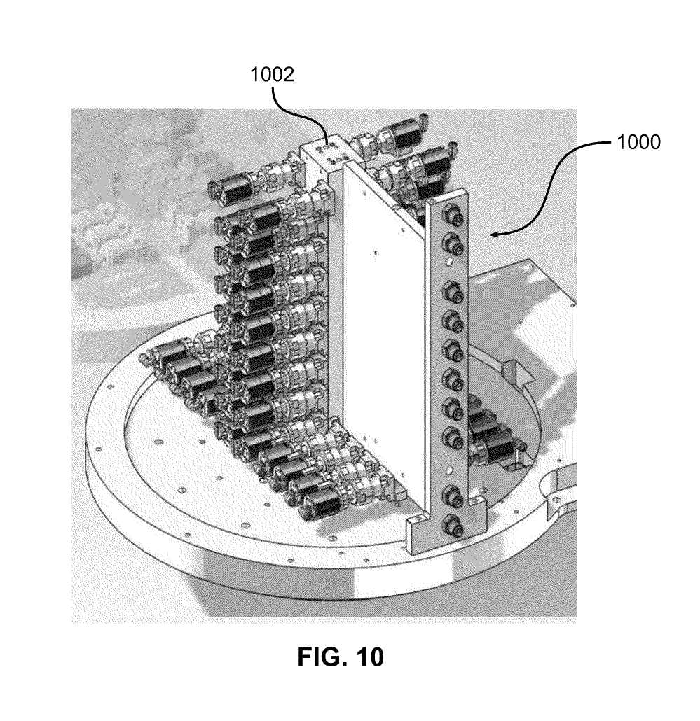

FIG. 10 illustrates a fluid conduit assembly 1000 (or at least a portion thereof) according to some embodiments. Of particular interest in FIG. 10 is that the fluid conduit assembly 1000 includes a single fluid conduit block 1002. In some embodiments, the fluid conduit block 1002 is used to form at least some of the fluid conduits in each of the multiple (e.g., four) sections (e.g., sections 800-806) of the module 400. That is, the single fluid conduit block 1002 may have an array of passageways formed therethrough which are used as the fluid conduits in more than one (e.g., all) of the sections in the module. As with the embodiment shown in FIG. 9, the fluid conduit block 1002 may be made of a single, integral piece of material (e.g., steel or aluminum).

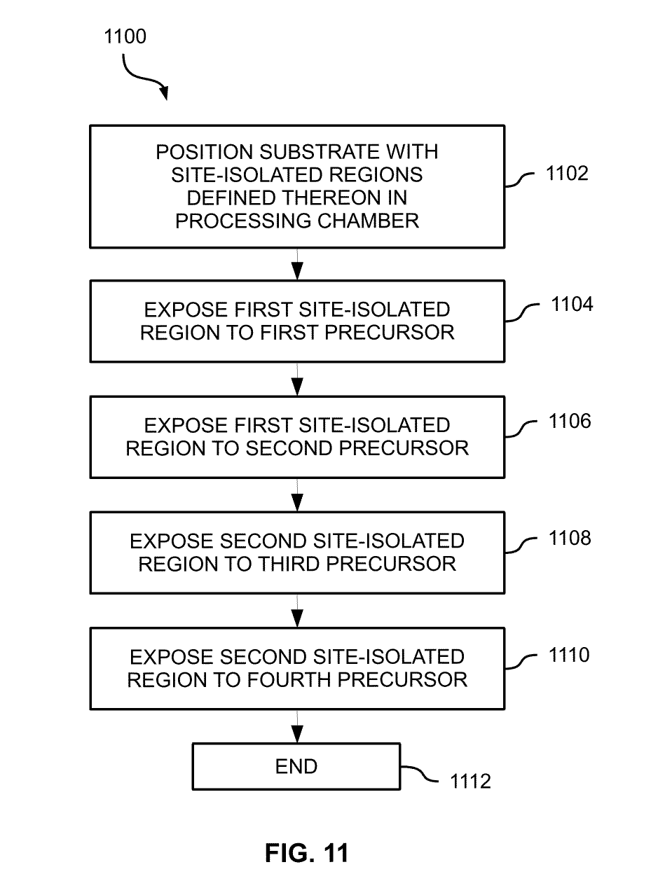

FIG. 11 is a flow chart of a method for performing a vapor deposition process on a substrate according to some embodiments. At block 1102, a substrate having a plurality of site-isolated regions defined thereon is positioned in a processing chamber of a vapor deposition (e.g., ALD or CVD) tool.

At block 1104, a first of the site-isolated regions is exposed to a first precursor (e.g., an ALD or CVD precursor). At block 1106, the first site-isolated region is exposed to a second precursor. At block 1108, a second of the site-isolated regions is exposed to a third precursor. At block 1110, the second site-isolated region is exposed to a fourth precursor.

In some embodiments, the exposing of the first and second site-isolated regions to the first, second, third, and fourth precursors occur while the substrate remains in the processing chamber. That is, the substrate is not moved into a second processing chamber or removed from the processing chamber between the various exposures. In some embodiments, the substrate remains in the (same) processing chamber from the initiation of the exposing of the first site-isolated region to the first precursor to the cessation of the exposing of the second site-isolated region to the fourth precursor. It should be understood that the order in which the exposures occur may be different than that depicted in FIG. 11, and some of the exposures may occur simultaneously. For example, the second site-isolated region may be exposed to the third precursor before the first site-isolated region is exposed to the second precursor, or even at the same time the first site-isolated region is exposed to the first precursor.

In some embodiments, method 1100 depicted in FIG. 11 involves the exposure of the site-isolated regions to reactants (e.g., first, second, third, and fourth reactants), either as additional steps, or as opposed to the exposure of the site-isolated regions to precursors. In some embodiments, some of the precursors and/or reactants have the same, or different, chemical composition. For example, the first precursor may have the same chemical composition as the fourth precursor, and/or the second precursor may have the same chemical composition as the third precursor. Likewise, the first precursor may have a different chemical composition than the third precursor, etc. In some embodiments, additional site-isolated regions are exposed to additional precursors and/or reactants (e.g., fifth, sixth, etc. precursors/reactants). At block 1112, the method 1100 ends.

Thus, in some embodiments, vapor deposition tools are provided. Each of the vapor deposition tools includes a housing defining a processing chamber. A substrate support is positioned within the processing chamber and configured to support a substrate. A fluid supply system including a plurality precursor sources is included. A fluid conduit assembly including a first section and a second section is coupled to the fluid supply system. The first section is configurable to selectively expose a first site-isolated region defined on the substrate to the respective precursors of a first and a second of the plurality of precursor sources. The second section is configurable to selectively expose a second site-isolated region defined on the substrate to the respective precursors of a third and fourth of the plurality of precursor sources.

In some embodiments, vapor deposition tools are provided. Each of the vapor deposition tools includes a housing defining a processing chamber. A substrate support is positioned within the processing chamber and configured to support a substrate. A backing plate is positioned above the substrate support. A showerhead is positioned between the substrate support and the backing plate. The showerhead has a plurality of openings therethrough and includes a fluid separation mechanism defining a first portion of the showerhead and a second portion of the showerhead. A fluid supply system including a plurality of precursor sources is included. A fluid conduit assembly including a first section and a second section is coupled to the fluid supply system. The first section of the fluid conduit assembly is configurable to selectively place the first portion of the showerhead in fluid communication with a first and a second of the plurality of precursor sources. The second section of the fluid conduit assembly is configurable to selectively place the second portion of the showerhead in fluid communication with a third and a fourth of the plurality of precursor sources.

In some embodiments, methods for performing a vapor deposition process on a substrate are provided. A substrate is positioned in a processing chamber. The substrate has a plurality of site-isolated regions defined thereon. A first of the plurality of site-isolated regions is exposed to a first precursor. The first of the plurality of site-isolated regions is exposed to a second precursor. A second of the plurality of site-isolated regions is exposed to a third precursor. The second of the plurality of site-isolated regions is exposed to a fourth precursor.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A vapor deposition tool comprising:
a housing defining a processing chamber;
a substrate support positioned within the processing chamber and configured to support a substrate;
a fluid supply system comprising a plurality precursor sources; and
a fluid conduit assembly comprising a first section and a second section coupled to the fluid supply system, wherein
the first section is configurable to selectively expose a first site-isolated region defined on the substrate to the respective precursors of a first and a second of the plurality of precursor sources, and
the second section is configurable to selectively expose a second site-isolated region defined on the substrate to the respective precursors of a third and fourth of the plurality of precursor sources.

2. The vapor deposition tool of claim 1, wherein the fluid supply system further comprises a plurality of reactant sources, and wherein
the first section of the fluid conduit assembly is further configurable to selectively expose the first site-isolated region to the respective reactants of a first and a second of the plurality of reactant sources, and
the second section of the fluid conduit assembly is further configurable to selectively expose the second site-isolated region to the respective reactants of a third and a fourth of the plurality of reactant sources.

3. The vapor deposition tool of claim 1, further comprising:
a backing plate positioned above the substrate support; and
a showerhead positioned between the substrate support and the backing plate, the showerhead having a plurality of openings therethrough and comprising a fluid separation mechanism defining a first portion of the showerhead and a second portion of the showerhead.

4. The vapor deposition tool of claim 3, wherein the first section of the fluid conduit assembly is further configurable to selectively place the first portion of the showerhead in fluid communication with the first and the second of the plurality of precursor sources, and
the second section of the fluid conduit assembly is further configurable to selectively place the second portion of the showerhead in fluid communication with the third and the fourth of the plurality of precursor sources.

5. The vapor deposition tool of claim 3, further comprising a first vacuum line coupled to the fluid conduit assembly between the plurality of precursor sources and the showerhead and a second vacuum line coupled to the fluid conduit assembly between the plurality of reactant sources and the showerhead.

6. The vapor deposition of tool of claim 5, wherein the fluid conduit assembly comprises a first valve coupled between the first vacuum line and the showerhead and a second valve coupled between the second vacuum line and the showerhead.

7. The vapor deposition tool of claim 2, wherein the first section of fluid conduit assembly is further configurable to selectively expose the first site-isolated region to the respective precursor of a fifth of the plurality of precursor sources, and
the second section of the fluid conduit assembly is further configurable to selectively expose the second site-isolated region to the respective precursor of a sixth of the plurality of precursor sources.

8. The vapor deposition tool of claim 2, wherein each of the respective precursors of the plurality of precursor sources is a atomic layer deposition (ALD) precursor or a chemical vapor deposition (CVD) precursor.

9. The vapor deposition tool of claim 3, wherein each of the respective reactants of the plurality of reactant sources is an ALD reactant or a CVD reactant.

10. The vapor deposition tool of claim 9, wherein the fluid conduit assembly comprises a plurality of fluid conduits, wherein at least some of the plurality of fluid conduits are jointly formed by a single, integral piece of material.

11. A vapor deposition tool comprising:
a housing defining a processing chamber;
a substrate support positioned within the processing chamber and configured to support a substrate;
a backing plate positioned above the substrate support;
a showerhead positioned between the substrate support and the backing plate, the showerhead having a plurality of openings therethrough and comprising a fluid separation mechanism defining a first portion of the showerhead and a second portion of the showerhead;
a fluid supply system comprising a plurality of precursor sources; and
a fluid conduit assembly comprising a first section and a second section coupled to the fluid supply system, wherein
the first section of the fluid conduit assembly is configurable to selectively place the first portion of the showerhead in fluid communication with a first and a second of the plurality of precursor sources, and
the second section of the fluid conduit assembly is configurable to selectively place the second portion of the showerhead in fluid communication with a third and a fourth of the plurality of precursor sources.

12. The vapor deposition tool of claim 11, wherein the fluid supply system further comprises a plurality of reactant sources, and wherein
the first section of the fluid conduit assembly is further configurable to selectively place the first portion of the showerhead in fluid communication with a first and a second of the plurality of reactant sources, and
the second section of the fluid conduit assembly is further configurable to selectively place the second portion of the showerhead in fluid communication with a third and a fourth of the plurality of reactant sources.

13. The vapor deposition tool of claim 12, wherein each of the respective precursors of the plurality of precursor sources is a atomic layer deposition (ALD) precursor or a chemical vapor deposition (CVD) precursor.

14. The vapor deposition tool of claim 13, wherein each of the respective reactants of the plurality of reactant sources is an ALD reactant or a CVD reactant.

15. The vapor deposition tool of claim 14, wherein the fluid conduit assembly comprises a plurality of fluid conduits, wherein at least some of the plurality of fluid conduits are jointly formed by a single, integral piece of material.

16. A method for performing a vapor deposition process on a substrate, the method comprising:
positioning a substrate in a processing chamber, the substrate having a plurality of site-isolated regions defined thereon;
exposing a first of the plurality of site-isolated regions to a first precursor;
exposing the first of the plurality of site-isolated regions to a second precursor;
exposing a second of the plurality of site-isolated regions to a third precursor; and
exposing the second of the plurality of site-isolated regions to a fourth precursor.

17. The method of claim 16, wherein the substrate remains in the processing chamber between the initiating of the exposing of the first of the plurality of site-isolated regions to the first precursor and the cessation of the exposing of the second of the plurality of site-isolated regions to the fourth precursor.

18. The method of claim 17, wherein the exposing of the second of the plurality of site-isolated regions to the third precursor occurs simultaneously with the exposing of the first of the plurality of site-isolated regions to the first precursor.

19. The method of claim 18, wherein the third precursor has a different chemical composition than the first precursor.

20. The method of claim 19, wherein each of the first, second, third, and fourth precursors is an atomic layer deposition (ALD) precursor or a chemical vapor deposition (CVD) precursor.
